(19) United States
(12) Patent Application Publication
(10) Pub. No.: US 2021/0201996 A1
(43) Pub. Date: Jul. 1, 2021

(54) REWRITE METHOD FOR VARIABLE RESISTANCE ELEMENT, AND NON-VOLATILE STORAGE DEVICE USING VARIABLE RESISTANCE ELEMENT

(71) Applicant: NEC Corporation, Minato-ku, Tokyo (JP)

(72) Inventors: Toshitsugu SAKAMOTO, Tokyo (JP); Naoki BANNO, Tokyo (JP); Munehiro TADA, Tokyo (JP); Yukihide TSUJI, Tokyo (JP)

(73) Assignee: NEC Corporation, Minato-ku, Tokyo (JP)

(21) Appl. No.: 16/756,554

(22) PCT Filed: Oct. 23, 2018
(86) PCT No.: PCT/JP2018/039252

§ 371 Date: Apr. 16, 2020

(30) Foreign Application Priority Data
Oct. 25, 2017 (JP) 2017-206267

(51) Int. Cl. G11C 13/00; H01L 27/24

(52) U.S. Cl. CPC G11C 13/0069; H01L 27/24; G11C 13/0023

(57) ABSTRACT

Provided are a rewrite method for a variable resistance element that increases a rewrite count, and a non-volatile storage device using the variable resistance element. In the rewrite method for the variable resistance element, a variable resistance layer is disposed between a first electrode and a second electrode, and a write voltage is applied between the first electrode and the second electrode, thereby causing the resistance between the first electrode and the second electrode to reversibly change. After writing to the variable resistance element, the variable resistance element is read, the read current is measured, the measured read current is compared with a reference current, a condition of the writing is changed on the basis of the comparison results, and thereafter writing to the variable resistance element is performed again.

### TECHNICAL FIELD

The present invention relates to a rewrite method for a variable resistance element and a non-volatile storage device using the variable resistance element, and in particular, to a rewrite method that increases a rewrite count of the variable resistance element.

### BACKGROUND ART

A variable resistance type non-volatile element (hereinafter, variable resistance element) is one of non-volatile storage elements having a two-terminal structure, in which a resistance state between the terminals is changed when voltage between both terminals is applied, and in a state in which the resistance value is maintained when no voltage is applied. Non-Patent Literature 1 (NPL1) proposes a variable resistance element composed of a variable resistance layer sandwiched between two metal electrodes (a first electrode and a second electrode). A resistance state of the variable resistance layer is reversibly changed when voltage between both electrodes is applied. In a state in which the resistance value is low (ON state), a metal crosslink or oxygen deficiency is formed in the variable resistance layer when voltage is applied. On the other hand, at the time of transition to a state in which the resistance value is high (OFF state), a part or all of the above metal crosslink or oxygen deficiency formed in the variable resistance layer is removed when reverse voltage to the voltage transitioning to the ON state is applied.

Such a variable resistance element is utilized for a non-volatile memory disclosed in Non-Patent Literature 2 (NPL2), a non-volatile switch of a non-volatile programmable logic disclosed in Non-Patent Literature 3 (NPL3), and the like. The non-volatile memory and the non-volatile switch require performance in such a way that the resistance value is retained for 10 years or larger equivalent to product life. In order to read a difference between the ON state and the OFF state, it is also desirable that a difference between ON and OFF resistance values be great. The non-volatile memory requires a resistance ratio of one digit, and the non-volatile switch requires a resistance ratio of equal to or more than four digits.

An operation of rewriting the variable resistance element to the ON state is referred to as a set operation, and an operation of rewriting the variable resistance element to the OFF state is referred to as a reset operation. Further, a first set operation after the manufacturing of the variable resistance element is referred to as a forming operation. A voltage for the forming operation (or forming voltage) is generally higher than a voltage required for the set operation. The variable resistance elements disclosed in NPL1 to NPL3 do not require the forming. The present patent application does not consider the forming, either.

The ON state resistance (ON resistance), as illustrated in FIG. 3 of NPL1, can be controlled by current flowing during the set operation and a current applied time (T_{P}). In general, there is a proportional relationship between a reverse number of the ON resistance (ON conductivity) and the current. The ON conductivity is also proportional to a logarithm of the current applied time. In addition, the current required for the reset operation is proportional to the ON conductivity. In NPL1, it is also described that, even when the current and the current applied time are identical, there is a variation in the ON resistance to be acquired. The ON resistance influences the current required for the reset operation and thus it is desirable that the variation be reduced to be as small as possible.

Patent Literature 1 (PTL1) and Patent Literature 2 (PTL2) propose a rewrite method for acquiring desired ON resistance in the set and the reset operations. According to PTL1, in the set or the reset operation, first, a voltage pulse of a predetermined pulse width is applied. A resistance value of the variable resistance element is read, and when it is determined that the resistance value is not within a target range, it is determined that write processing does not normally complete, then a voltage pulse is applied under a second application condition. The voltage pulse is repeatedly applied until the read resistance value falls within the target range. An operation of performing voltage application until a target value is acquired is referred to as a verify operation. In PTL1, a voltage value and a pulse width of a voltage pulse are set depending on the read resistance value. PTL2 describes a method of increasing a voltage of a voltage pulse during the verify operation.

Patent Literature 3 (PTL3) proposes a method of applying, in sequential order, pulse voltages with different positive and negative polarities during the set and the reset operations. During the verify operation as well, a similar pulse voltage pair is applied. Between the two pulses, an amplitude of a first pulse voltage is set to be smaller than a subsequent pulse voltage.

Patent Literature 4 (PTL4) proposes a method of alternately applying voltages with different polarities between both electrodes of the variable resistance element in the forming operation. First, a voltage pulse with a predetermined pulse width is applied between the both electrodes. A resistance value of the variable resistance element is read, and it is determined whether there is a change from a high resistance state after the manufacturing of the variable resistance element to a low resistance state. When there is no change to the low resistance state, a voltage with reverse polarity to that of the first applied voltage is applied. At this time, there is a change to the low resistance state with a lower voltage than the first applied voltage. When there is no change to the low resistance state even when the voltage with reverse polarity is applied, the same operation, that is, the operation of alternately applying voltage pulses with different polarities is repeated until the variable resistance element changes to the low resistance state. PTL4 uses a phenomenon that the forming occurs with a negative voltage.

Patent Literature 5 (PTL5) proposes a method of driving a non-volatile semiconductor storage device including a variable resistance element in which a write voltage is applied between both terminals, thereby enabling mutual transition depending on an application condition between a first resistance state and a second resistance state different from the first resistance state, and the application condition enabling transition of the resistance state depends on the application condition of the applied write voltage during an immediately preceding transition. Patent Literature 6 (PTL6) proposes a resistance state change method of a variable resistance type element for changing a resistance state of the variable resistance type element, by executing setting of switching a resistance state of the variable resistance type element from a high resistance state to a low resistance state by applying a first pulse voltage of one or more times to the variable resistance type element, and executing resetting of switching the resistance state of the variable resistance type element from the high resistance state to the low resistance state by applying a second pulse voltage different from the first pulse voltage of one or more times to the variable resistance type element.

### CITATION LIST

### Patent Literature

[PTL1] Japanese Patent Application Laid-open No. 2012-64286

[PTL2] Japanese Patent Application Laid-open No. 2005-25914

[PTL3] Japanese Patent Application Laid-open No. 2014-225316

[PTL4] Japanese Patent Application Laid-open No. 2016-212942

[PTL5] Japanese Patent Application Laid-open No. 2009-146469

[PTL6] Japanese Patent Application Laid-open No. 2013-48004

### Non Patent Literature

[NPL1] “Impact of overshoot current on set operation of atom switch”, Japanese Journal of Applied Physics 53, 04ED07 (2014). [NPL2] “Low-power embedded read-only memory using atom switch and silicon-on-thin-buried-oxide transistor”, Applied Physics Express 8, 045201 (2015).

[NPL3] “0.5-V Highly Power-Efficient Programmable Logic using Nonvolatile Configuration Switch in BEOL”, Proceeding, FPGA '15 Proceedings of the 2015 ACM/SIGDA International Symposium on Field-Programmable Gate Arrays, Pages 236 to 239.

### SUMMARY OF INVENTION

### Technical Problem

In order to resistively change a large number of variable resistance elements including a characteristic variation, applied voltage, applied time, and applied current may be increased to be as great as possible. On the other hand, when the applied voltage, the applied time, and the applied current are increased in order to rewrite even a small number of variable resistance elements in which a rewrite failure is likely to occur, excessive voltage and current are applied to a large number of variable resistance elements over a long period of time. Consequently, element degradation of the variable resistance element progresses, and the rewrite count of the variable resistance element is limited.

An object of the present invention is to provide a rewrite method for a variable resistance element, which increases a rewrite count, and a non-volatile storage device using the variable resistance element.

### Solution to Problem

In order to achieve the object, a rewrite method for a variable resistance element according to the present invention is a rewrite method for a variable resistance element in which a variable resistance layer is disposed between a first electrode and a second electrode, and a resistance between the first electrode and the second electrode is reversibly changed by applying a write voltage between the first electrode and the second electrode, the rewrite method for the variable resistance element comprises:

after writing to the variable resistance element, reading the variable resistance element and measuring a read current; and

comparing the measured read current with a reference current, changing a condition of the writing, based on the comparison result, and thereafter rewriting to the variable resistance element.

A non-volatile storage device using a variable resistance element according to the present invention comprises:

the variable resistance element in which a variable resistance layer is disposed between a first electrode and a second electrode, and a resistance between the first electrode and the second electrode is reversibly changed by applying a write voltage between the first electrode and the second electrode; and

a control unit that is capable of applying voltage to the variable resistance element and is capable of comparing current flowing in the variable resistance element with a reference current, wherein

the control unit performs:

measurement processing of, after writing to the variable resistance element, reading the variable resistance element and measuring a read current;

comparison processing of comparing the measured read current with a reference current; and

changing a condition of the writing, based on the comparison result of the comparison processing, and thereafter rewriting to the variable resistance element.

### Advantageous Effects of Invention

The present invention is able to provide a rewrite method and a non-volatile storage device that increase a rewrite count for a variable resistance element.

### BRIEF DESCRIPTION OF DRAWINGS

FIG. 1 is a schematic diagram illustrating a configuration of a variable resistance element cell used in a non-volatile storage device according to a first example embodiment.

FIG. 2 is a schematic diagram illustrating a mechanism in which an ON resistance is determined depending on a current value used in the non-volatile storage device according to the first example embodiment and a second example embodiment, wherein (a) is a schematic diagram at a time when current is great, and (b) is a schematic diagram at a time when current is small.

FIG. 3 is a schematic diagram illustrating a change at a time when a metal crosslink is formed and eliminated in a variable resistance element in the non-volatile storage device according to the first and second example embodiments.

FIG. 4 is a graph illustrating the number of failures at a time when rewriting is performed without using verifying in a 128 Kbits variable resistance element according to the first and second example embodiments, wherein (a) is a graph during a set operation, and (b) is a graph during a reset operation.

FIG. 5 is a circuit diagram illustrating a part of the configuration of the non-volatile storage device according to the first example embodiment.

FIG. 6A is a table illustrating one example of an application condition of the set operation and a reference current during reading in the non-volatile storage device according to the first example embodiment.

FIG. 6B is a flowchart illustrating the set operation in the non-volatile storage device according to the first example embodiment.

FIG. 7A is a table illustrating one example of an application condition of the reset operation in the non-volatile storage device according to the first example embodiment.

FIG. 7B is a flowchart illustrating the reset operation in the non-volatile storage device according to the first example embodiment.

FIG. 8A is a table illustrating one example of an application condition of a set operation and a reference current during reading in the non-volatile storage device according to the second example embodiment.

FIG. 8B is a flowchart illustrating the set operation in the non-volatile storage device according to the second example embodiment.

FIG. 9 is a graph illustrating transition of the number of faulty bits at the time of each verifying during a verify operation according to the second example embodiment.

FIG. 10A is a table illustrating one example of an application condition of a reset operation and a reference current during reading in the non-volatile storage device according to the second example embodiment.

FIG. 10B is a flowchart illustrating the reset operation in the non-volatile storage device according to the second example embodiment.

FIG. 11 is a graph illustrating the number of failures at a time when rewriting is performed by using the verifying in the 128 Kbits variable resistance element according to the second example embodiment, wherein (a) is a graph during the set operation, and (b) is a graph during the reset operation.

### EXAMPLE EMBODIMENT

Preferred example embodiments of the present invention will be described in detail with reference to the drawings.

### Findings Forming Basis of the Present Invention

The following analysis is given by the inventors of the present patent application.

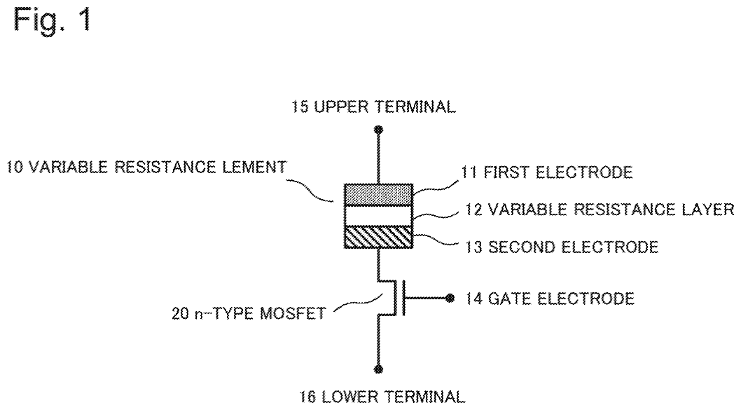

A transistor is connected in series to a variable resistance element and controls current and voltage flowing during rewriting. FIG. 1 is a schematic diagram illustrating a configuration of a variable resistance element cell used in a non-volatile storage device. In the variable resistance element cell of FIG. 1, a variable resistance element 10 is connected in series to an n-type metal oxide semiconductor field effect transistor (MOSFET) 20. The variable resistance element 10 is composed of three layers of a first electrode 11, a variable resistance layer 12, and a second electrode 13, and a resistance between the first electrode 11 and the second electrode 13 is reversibly changed when a write voltage between the first electrode 11 and the second electrode 13 is applied. A drain of the n-type MOSFET 20 and the second electrode 13 of the variable resistance element 10 are connected. An upper terminal 15 is connected to the first electrode 11 of the variable resistance element 10, and a lower terminal 16 is connected to a source of the n-type MOSFET 20. In addition, the n-type MOSFET 20 includes a gate electrode 14. The first electrode 11 of the variable resistance element 10 is composed of a metal easy to ionize, for example, copper; the second electrode 13 is composed of a metal not easy to ionize, for example, ruthenium; and the variable resistance layer 12 is composed of a solid electrolyte in which a copper ion is conductive.

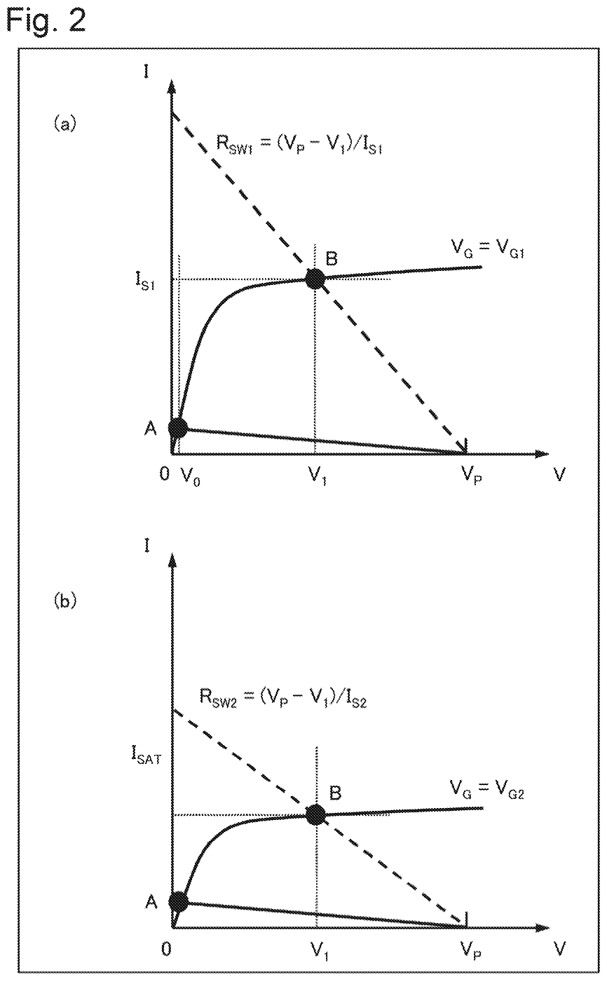

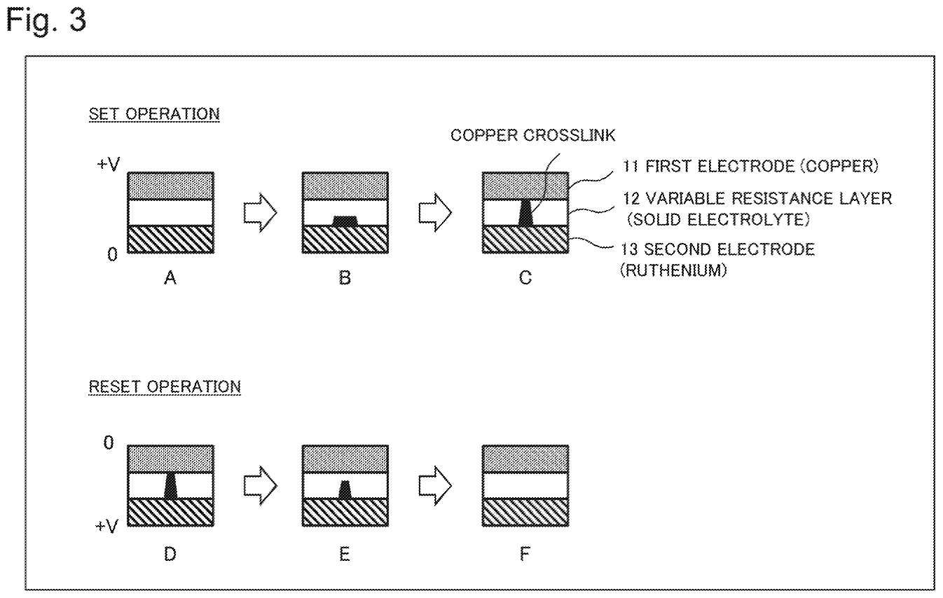

FIG. 3 is a schematic diagram illustrating a change at a time when a metal crosslink is formed and eliminated in the variable resistance element used in the non-volatile storage device. The variable resistance element after the manufacturing is in an OFF state (A of FIG. 3). In a set operation, a positive voltage V_{P} is applied to the upper terminal 15; 0 V is applied to the lower terminal 16; and positive voltage is applied to the gate electrode 14. FIG. 2 is a schematic diagram illustrating a mechanism in which an ON resistance is determined by a current value used in the non-volatile storage device, wherein (a) is a schematic diagram at a time when current is great, and (b) is a schematic diagram at a time when the current is small. An operating point at a time when a variable resistance element in the OFF state before a resistance change occurs is assumed to be a load resistance can be expressed as a point A of FIG. 2(a) or FIG. 2(b). Specifically, this point is given by a crossing point (point A) of a voltage/current characteristic of the n-type MOSFET 20 and a load straight line exerted by the variable resistance element 10. Assuming that an initial resistance value of the variable resistance element 10 is R₀, the load straight line (relational formula of a voltage V and a voltage I) exerted by the variable resistance element 10 is given by I=(V_{P}−V)/R₀. At this time, a voltage of (V_{P}−V₀) is applied between the first electrode 11 and the second electrode 13 of the variable resistance element 10, copper being a material for the first electrode 11 is ionized by voltage application, and diffuses in the solid electrolyte of the variable resistance layer 12. When the diffused copper ion reaches the second electrode 13, the copper ion receives an electron and becomes a metal copper and then the metal copper precipitates in the solid electrolyte of the variable resistance layer 12 (B of FIG. 3). When the precipitated copper reaches the first electrode 11, a copper crosslink is formed between the first electrode 11 and the second electrode 13, and a resistance value of the variable resistance element 10 changes to a low resistance state (C of FIG. 3). At this time, the operating point traces on the current/voltage characteristic of the n-type MOSFET 20 from the point A to a point B in FIG. 2(a) and FIG. 2(b). At the point B, the voltage applied to the variable resistance element 10 becomes (V_{P}−V₁), and the voltage decreases as compared with the state before the resistance change starts. Consequently, a speed at which a copper crosslink grows is restrained.

This leads that, as illustrated in FIG. 3 of NPL1, the ON resistance of the variable resistance element is proportional to a logarithm of a voltage applied time. The longer the voltage applied time is, the larger the thickness of the copper crosslink is and the lower the resistance is, however, the voltage applied to the variable resistance element decreases simultaneously, and therefore, the growth speed is further restrained.

As illustrated in FIG. 1, by connecting the n-type MOSFET 20 to the variable resistance element 10 in series, a restraining function works relative to the growth speed of the copper crosslink, and the ON resistance is determined. By utilizing this restraining function, the ON resistance of the variable resistance element 10 can be controlled by using a saturation current (I_{S}) of the n-type MOSFET 20. FIG. 2(b) illustrates a case where the saturation current is small as compared with that of FIG. 2(a) (I_{S2}<I_{S1}). From a relationship with the load straight line exerted by the variable resistance element 10, the ON resistance R_{SW1}=(V_{P}−V₁)/I_{S1} holds in FIG. 2(a), and the ON resistance R_{SW2}=(V_{P}−V₁)/I_{S2} holds in FIG. 2(b). In FIG. 2(b), it is found that the ON resistance of the variable resistance element 10 is higher at the same voltage V₁ (R_{SW2}>R_{SW1}). From this fact, as illustrated in FIG. 3 of NPL1, an experimental result that the ON resistance changes due to the transistor saturation current (or gate voltage) can be described.

In a reset operation, the copper crosslink formed between the electrodes is cut (E of FIG. 3), and the copper is re-collected in the first electrode 11 (F of FIG. 3) to cause the variable resistance element 10 to change from a low resistance state to a high resistance state. The copper crosslink is cut by current flowing in an opposite direction to the direction in which copper is grown. When a part of the copper crosslink is cut, voltage is applied to both electrodes, and the remaining copper can be ionized and re-collected. At the time of the resetting, 0 V is applied to the upper terminal 15 of the variable resistance electrode cell, positive voltage is applied to the lower terminal 16, and positive voltage is applied to the gate electrode 14 in FIG. 1.

The ON resistance value of the variable resistance element 10 influences reliability of the ON state. Specifically, the lower the ON resistance is, the longer the time for maintaining the ON state is. It is important to maintain the ON state or the OFF state for a non-volatile element. On the other hand, in order to reduce the ON resistance, as described above, a large current value for the reset operation, namely a large size transistor is required. Consequently, the cell size being an important factor for a memory increases.

In addition, when the set or the reset operation is performed on a large number of variable resistance elements, the large number of variable resistance elements may include a faulty element of which resistance state does not change since the element characteristics in the large number of variable resistance elements vary.

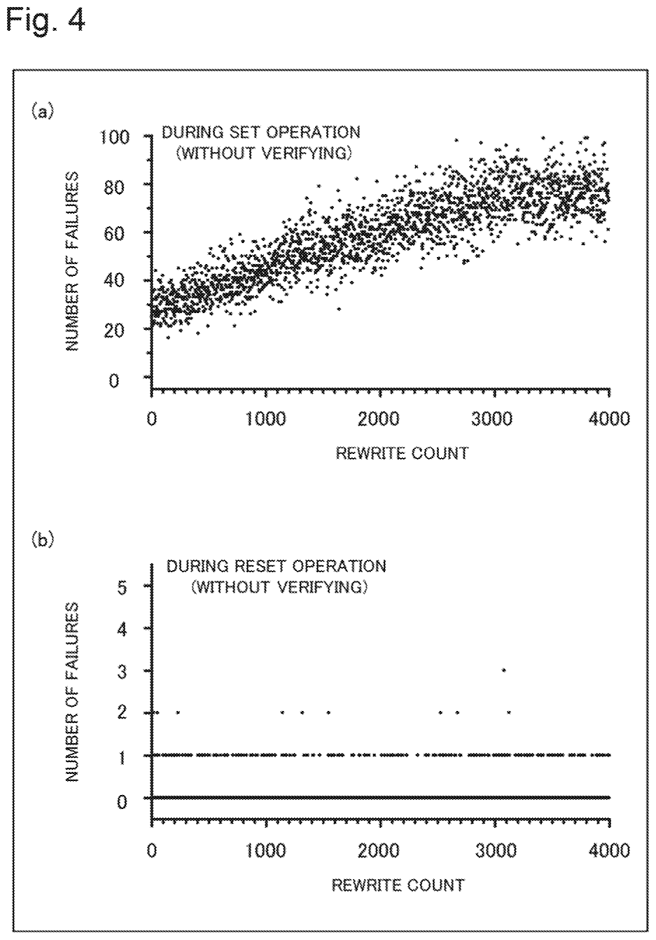

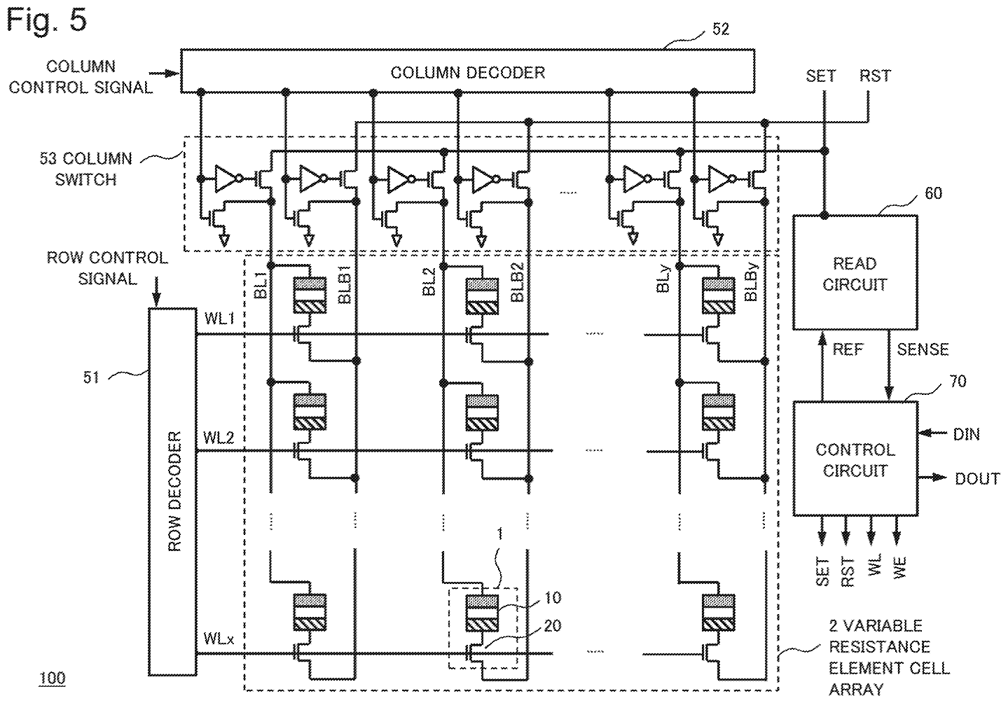

FIG. 4 is a graph illustrating the number of failures at a time when rewriting is performed without using verifying in a variable resistance element, and (a) is a graph illustrating the set operation and (b) is a graph illustrating the reset operation. FIG. 4(a) and FIG. 4(b) illustrate the number of failures during the setting and the resetting relative to rewriting of up to 4,000 times. The number of the variable resistance elements is 128 Kbits in total. During the set operation in FIG. 4(a), failures of about 20 to 100 are found in each rewriting. During the reset operation in FIG. 4(b) as well, no failure occurs in most cases, however, bits of about 1 to 3 do not change to the low resistance state. This experiment uses a non-volatile storage device 100 in FIG. 5 which will be described later.

Causes of failure that occurs due to a variation during the set operation are as follows.

(S-i) A threshold voltage at which a resistance change occurs is greater than applied voltage.
(S-ii) Time is required from application of voltage to the start of a resistance change.
(S-iii) A generated copper crosslink is thin and thus is cut by current flowing in the crosslink.
(S-iv) A copper electrode or a solid electrolyte is degraded by repeated rewritings, and copper diffusion is restrained.

First, the cause of failure (S-i) is clarified according to an experimental fact that the number of failures is reduced when the voltage applied between the first electrode 11 and the second electrode 13 of the variable resistance element 10 is increased. The cause of failure (S-ii) is clarified according to an experimental fact that the number of elements in which no resistance change occurs is reduced when one increases the applied time. The cause of failure (S-iii) is clarified according to an experimental fact that when the current flowing in the variable resistance element is observed during the set operation, the current occasionally fluctuates, and the resistance state reverts to the original high resistance state in spite of temporarily changing to the low resistance state. This is equivalent to a case where the retention time is extremely short. This failure can be prevented when one increases the current during the set operation to write in a lower resistance state. The cause of failure (S-iv), as illustrated in FIG. 4, is clarified according to the fact that the number of failures increases as the rewrite count increases.

On the other hand, causes of failure that occurs due to a variation during the reset operation are as follows.

(R-i) Current at which a resistance change occurs is greater than applied current. Herein, voltage is proportional to current by the Kirchhoff law and thus the current at which the resistance change occurs can be hereinafter considered to be the threshold voltage.
(R-ii) Time is required from application of voltage and the start of a resistance change.
(R-iii) A solid electrolyte is degraded by repeated rewritings, and copper diffusion is restrained.

The above three causes of failure are considered.

### First Example Embodiment

As described above, in order to resistively change a number of elements including a characteristic variation, applied voltage, applied time, and applied current should be increased to be as great as possible. On the other hand, when the applied voltage, the applied time, and the applied current are increased in order to rewrite even a small number of variable resistance elements in which a rewrite failure is likely to occur, excessive voltage and current are applied to a large number of variable resistance elements over a long period of time. Consequently, element degradation of the variable resistance element progresses, and the rewrite count of the variable resistance element is limited as described with respect to the cause of failure (S-iv) during a set operation or the cause of failure (R-iii) during a reset operation. Therefore, it is appropriate to cause a faulty bit of which characteristic deviates from a large number of bits to resistively change by verify writing.

Next, a rewrite method for a variable resistance element according to a first example embodiment will be described together with a non-volatile storage device including a verify function according to the first example embodiment. FIG. 5 is a circuit diagram illustrating a configuration of a part of the non-volatile storage device according to the first example embodiment.

A non-volatile storage device 100 is a storage device having the variable resistance element 10 illustrated in FIG. 1 as a non-volatile element (refer to FIG. 5). The non-volatile storage device 100 in FIG. 5 includes a variable resistance element cell array 2, a row decoder 51, a column decoder 52, a column switch 53, a read circuit 60, and a control circuit 70 as one example of a control unit.

The variable resistance element cell array 2 is a portion in which a plurality of variable resistance element cells 1 are disposed in a two-dimensional manner. In the variable resistance element cell array 2 in FIG. 5, the variable resistance element cells 1 are disposed in a row X and a column Y. A configuration of the variable resistance element cell 1 (variable resistance element 10 and n-type MOSFET 20) is as described previously (refer to FIG. 1). In the variable resistance element cell array 2, one end of the variable resistance element 10 in each of the variable resistance element cells 1 that are present in a same column is electrically connected to a SET terminal of the control circuit 70 and the read circuit 60 via a relevant bit line (any one of BL1 to BLy in FIG. 5) and the column switch 53. One end of the n-type MOSFET 20 in each of the variable resistance element cells 1 that are present in a same column is also electrically connected to an RST terminal of the control circuit 70 via a relevant bit line (any one of BLB1 to BLBy in FIG. 5) and the column switch 53. In addition, in the variable resistance element cell array 2, a gate electrode of the n-type MOSFET 20 in each of the variable resistance element cells 1 that are present in a same row is electrically connected to the row decoder 51 via a relevant word line (any one of WL1 to WLx in FIG. 5).

The row decoder 51 is a decoder that is capable of selecting one word line from among a plurality of word lines WL1 to WLx that are disposed in the x row. A voltage identical to that of a WL terminal is output to the selected word line. An input terminal WL of the row decoder 51 is connected to a WL terminal of the control circuit 70. An address terminal is included in a row control signal. The row decoder 51 functions, in cooperative operation with the column decoder 52, as a cell selection circuit that selects one variable resistance element 10 from the variable resistance element cell array 2. The row decoder 51 selects one word line from among the word lines WL1 to WLx in response to an address signal from the control circuit 70, and applies voltage via the selected word line to the n-type MOSFET 20 that is electrically connected to the selected word line. Thus, the row decoder 51 can select the variable resistance element cell 1 (variable resistance element 10 and n-type MOSFET 20) that is present in one row from the variable resistance element cell array 2.

The column decoder 52 is a decoder that is capable of selecting one bit line from among a plurality of bit lines BL1 to BLy and BLB1 to BLBy that are disposed in a y×2 column. During the set operation, one bit line is selected from among bit lines BL1 to BLy. For example, when the bit line BLy is selected, one of the relevant y×2 column switches 53 is selected, and the bit line BLy, the SET terminal of the control circuit 70, and the read terminal 60 are electrically connected. The bit lines BL1 to BLy−1 that are not selected are grounded via the column switch 53. During the reset operation, one bit line is selected from among the bit lines BLB1 to BLBy. For example, when the bit line BLBy is selected, one of the relevant y×2 column switches 53 is selected, and the bit line BLBy and the RST terminal of the control circuit 70 are electrically connected. The bit lines BLB1 to BLBy−1 that are not selected are grounded via the column switch 53.

The column decoder 52 functions, in cooperative operation with the row decoder 51, as a cell selection circuit that selects one variable resistance element 10 from the variable resistance element cell array 2. The column decoder 52 selects, in response to an address signal from the control circuit 70, one bit line from among the bit lines BL1 to BLy and BLB1 to BLBy when one applies voltage to a gate electrode of any one of column transistors, and via the selected bit line, the variable resistance element 10 that is electrically connected to the selected bit line, the read circuit 60, and the control circuit 70 are electrically connected.

The read circuit 60 is a circuit that is capable of reading a resistance value of the variable resistance element 10. The read circuit 60 is capable of applying a read voltage to the selected variable resistance element 10. The read circuit 60 is also capable of comparing current flowing in the selected variable resistance element 10 with a reference current I_{R}. The read circuit 60 receives control of the control circuit 70, reads the selected variable resistance element 10, and outputs the result SENSE to the control circuit 70.

The control circuit 70 is a circuit that controls the row decoder 51, the column decoder 52, and the read circuit 60. The control circuit 70 selects the variable resistance element 10 via the row decoder 51, the column decoder 52 and the n-type MOSFET 20. The control circuit 70 applies the read voltage to the selected variable resistance element 10 via the read circuit 60. The control circuit 70 performs, when it is determined that normal writing to the variable resistance element 10 is not performed by the read circuit 60, the repetition of rewriting process relative to the relevant variable resistance element 10. The control circuit 70 sets an application condition, and applies a write voltage to the variable resistance element 10.

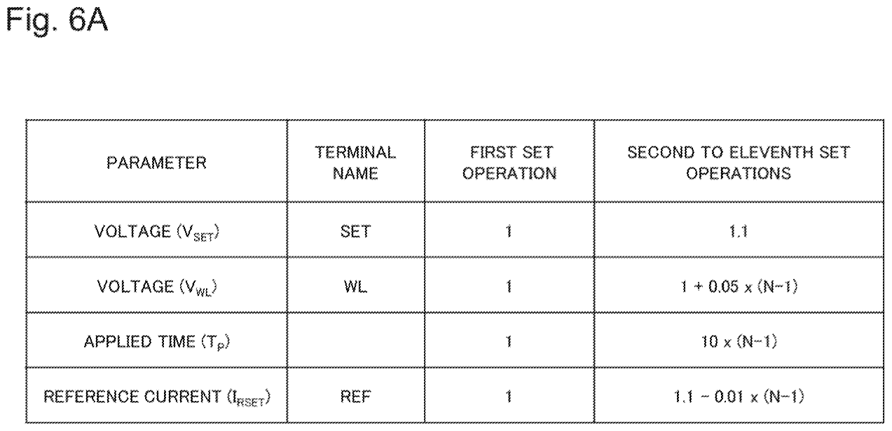

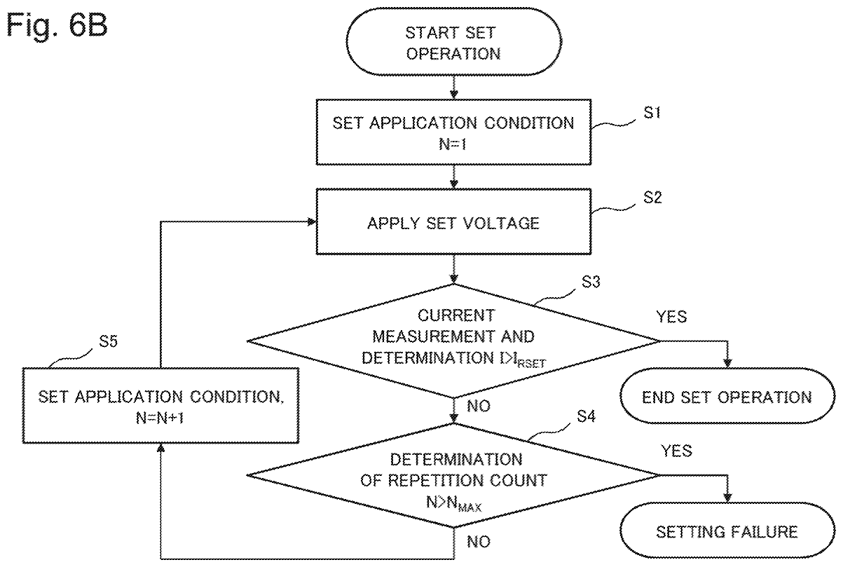

Next, the set operation of each variable resistance element 10 will be described with reference to the flowchart in FIG. 6B. The set operation is implemented, in response to an address signal, relative to the variable resistance element 10 that is selected by the row decoder 51 and the column decoder 52. The application condition for applying voltage to each terminal is set, and N=1 is set as a set operation count (step S1). The voltage is applied to each terminal under the voltage application condition of a first set operation (step S2). As parameters, for example, a set voltage V_{SET} is 3.0 V, a gate voltage V_{WL} applied to the n-type MOSFET 20 is 0.7 V, the applied time is 1 μs, and the reference current is 20 μA. When the gate voltage V_{WL}=0.7 V is applied, a saturation current value of the n-type MOSFET 20 is about 200 μA. Next, the variable resistance element 10 is read, the current is measured, and it is determined whether the measured current is greater than a reference current I_{RSET} (step S3). When the current flowing in the variable resistance element 10 is greater than the reference current I_{RSET} (YES in step S3), the set operation is completed. When the current flowing in the variable resistance element 10 is equal to or smaller than the reference current I_{RSET} (NO in step S3), an application condition for applying voltage to each terminal is set in order to perform the set operation twice (=N), N=N+1 is set (step S5), and the voltage is applied to each terminal (step S2).

The application condition of a second set operation that is a first verifying is as illustrated in the chart of FIG. 6A. In order to deal with the above cause of failure (S-i) during the set operation, the voltage applied to the SET terminal is increased by 10%. Further, in order to deal with the cause of failure (S-ii), the applied time is increased by 10 times. Furthermore, in order to deal with the cause of failure (S-iii), voltage for the WL terminal, which is the gate voltage of the n-type MOSFET 20, is increased by 5%. At this time, the saturation current of the n-type MOSFET 20 increases by about 5%. The voltage and the applied time increase according to N during the verifying, thereby making it possible to deal with the cause of failure (S-iv). Still furthermore, in order to secure a margin during reading, an ON/OFF criterion is transitioned to the low resistance side. Namely, the reference current is increased by 9%. The variation during determination can be reduced by transitioning the criterion to the low resistance side. As N increases, the criterion is mitigated in such a way as to approach the original criterion, and an occurrence of a setting failure is prevented.

After the second set operation, the variable resistance element 10 is read in step S3, the current is measured, and it is determined whether the measured current is greater than the reference current I_{RSET}. The set operation is completed when the current flowing in the variable resistance element 10 is greater than the reference current I_{RSET}, which means the reading is determined to satisfy the condition. Then, a next variable resistance element 10 is selected, and a similar operation illustrated in FIG. 6B is repeated.

When the set operation count N is greater than the maximum number N_{MAX} (N_{MAX}=11 in the case of FIG. 6A and FIG. 6B) (YES in step S4), it is determined to be a setting failure.

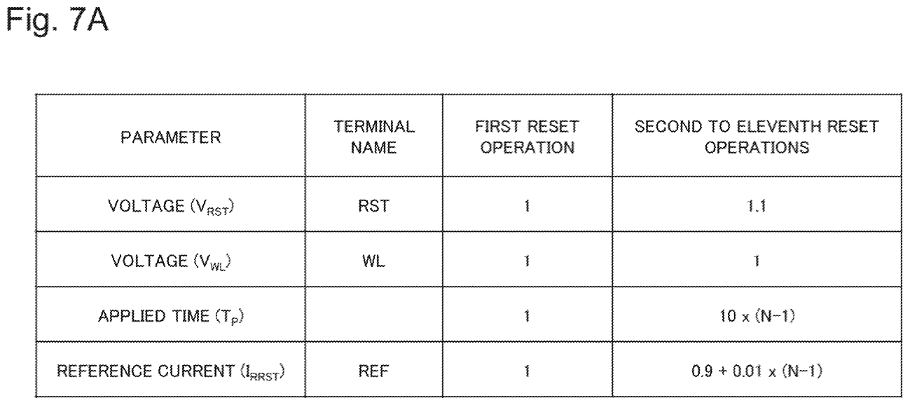

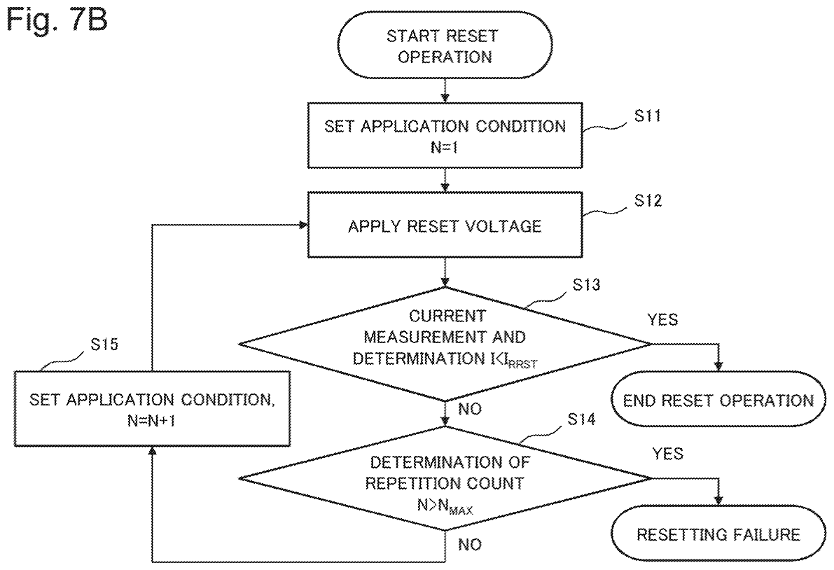

Next, the reset operation of each variable resistance element 10 will be described with reference to the flowchart in FIG. 7B. The reset operation is performed in response to an address signal, relative to the variable resistance element 10 that is selected by the row decoder 51 and the column decoder 52. The application condition for applying voltage to each terminal is set, and N=1 is set as a reset operation count (step S11). The voltage is applied to each terminal under the voltage application condition of a first reset operation (step S12). As parameters, for example, a reset voltage V_{RST} is 2.4 V, the gate voltage V_{WL} applied to the n-type MOSFET 20 is 2.8 V, the applied time is 200 ns, and the reference current is 20 μA. Next, the variable resistance element 10 is read, the current is measured, and it is determined whether the measured current is smaller than the reference current I_{RRST} (step S13). When the current flowing in the variable resistance element 10 is smaller than the reference current I_{RRST} (YES in step S13), the reset operation is completed. When the current flowing in the reference change element 10 is equal to or greater than the reference current I_{RRST}, an application condition for applying voltage to each terminal is set in order to perform the reset operation twice (=N), N=N+1 is set (step S15), and the voltage is applied to each terminal (step S12).

The application condition of a second reset operation that is a first verifying is as illustrated in the chart of FIG. 7A. In order to deal with the above cause of failure (R-i) during the reset operation, the voltage applied to the SET terminal is increased by 10%. Further, in order to deal with the cause of failure (R-ii), the applied time is increased by 10 times. Furthermore, the voltage and the applied time increase according to N during the verifying, thereby making it possible to deal with the cause of failure (R-iii). Still furthermore, in order to secure a margin during reading, the ON/OFF criterion is transitioned to the low resistance side. Namely, the reference current I_{RRST} is reduced by 10%. The variation during determination can be reduced when one moves the criterion to the high resistance side. As the reset operation count N increases, the criterion is mitigated in such a way as to approach the original criterion, and an occurrence of a resetting failure is prevented.

After the second reset operation, the variable resistance element 10 is read, the current is measured, and it is determined whether the measured current is smaller than the reference current I_{RRST} in step S13. The reset operation is completed when the current flowing in the variable resistance element 10 is smaller than the reference current I_{RRST}, which means the reading is determined to satisfy the condition. Then, a next variable resistance element 10 is selected, and a similar operation illustrated in FIG. 6B is repeated.

When the reset operation count N is greater than the maximum number N_{MAX} (N_{MAX}=11 in the case of FIG. 7A and FIG. 7B) (YES in step S14), it is determined to be a resetting failure.

When the technique for the set operation of FIG. 6A and FIG. 6B and the reset operation of FIG. 7A and FIG. 7B is applied and then the number of rewriting times of 128 Kbits is checked, the number of faulty bits found in FIG. 4 can be reduced, and the number of setting and resetting failures becomes 0 in the range up to 3,000 rewriting times.

The application conditions of FIGS. 6A and 6B and FIGS. 7A and 7B are results of optimization that is performed in such a way that the number of faulty bits becomes minimal, and it is possible to reduce the number of failures even when any of voltage adjustment, applied time adjustment, and reference current adjustment is performed. The range of adjustment may also be a value other than the values specifically illustrated in FIGS. 6A and 6B and FIGS. 7A and 7B. In addition, the maximum number N_{MAX} is not limited to 11.

### Second Example Embodiment

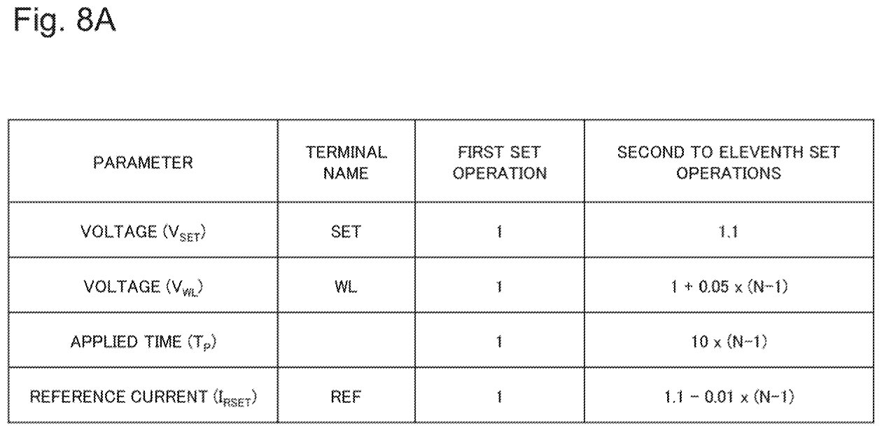

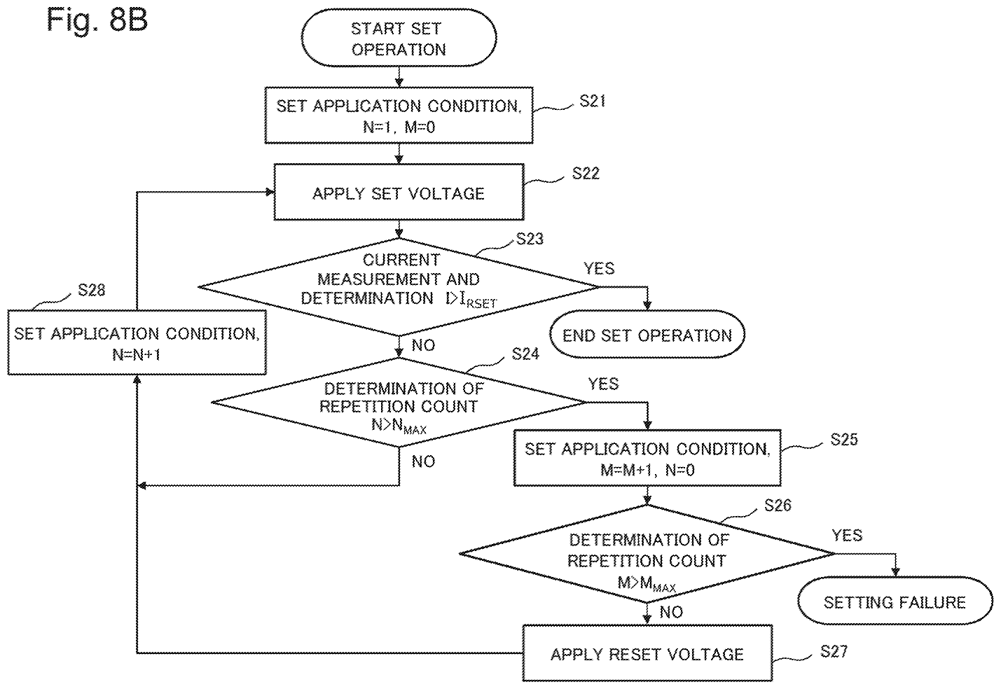

Next, a rewrite method for a variable resistance element according to a second example embodiment will be described. In the 128 Kbits rewrite experiment of the first example embodiment, some faulty bits are observed after 3,000 times. Herein, after a failure is observed during a set operation, when a reset operation and the further set operation are implemented, the number of failures becomes 0, and thus the number of failures should be able to be further reduced when the verifying is performed in the flow of FIG. 8B. Namely, in the set operation, the verify operation of the second example embodiment is implemented, then the reset operation is implemented, and the further verifying during the set operation is implemented. The present example embodiment uses a non-volatile storage device including the verify function according to the first example embodiment, and therefore, a detailed description of the non-volatile storage device is omitted.

A flow of the set operation according to the present example embodiment will be described with reference to FIG. 8B. The set operation is implemented in response to an address signal, relative to a variable resistance element 10 that is selected by a row decoder 51 and a column decoder 52. An application condition for applying voltage to each terminal is set, N=1 is set as a set operation count, and M=0 is set as a reset operation count (step S21). The voltage is applied to each terminal under the voltage application condition of a first set operation (step S22). Next, the variable resistance element 10 is read, the current is measured, and it is determined whether the measured current is greater than a reference current I_{RSET} (step S23). When the current flowing in the variable resistance element 10 is greater than the reference current I_{RSET} (YES in step S23), the set operation is completed. When the current flowing in the variable resistance element 10 is equal to or smaller than the reference current I_{RSET} (NO in step S23), an application condition for applying voltage to each terminal is set in order to perform the set operation twice (=N), N=N+1 is set (step S28), and the voltage is applied to each terminal (step S22). The application condition of a second set operation that is a first verifying is as illustrated in the chart of FIG. 8A. Herein, voltage applied to a SET terminal is increased by 10%. Further, applied time is increased by 10 times. Furthermore, voltage for a WL terminal, which is a gate voltage of an n-type MOSFET 20, is increased by 5%. Still furthermore, in order to secure a margin during reading, an ON/OFF criterion is transitioned to the low resistance side.

When the set operation count N is greater than the maximum number N_{MAX} (N_{MAX}=11), the reset operation is performed by using the application condition of N=1 of FIG. 7B described according to the first example embodiment (step S27). Herein, N is set to 1, and the verifying of the set operation is subsequently implemented after the reset operation. It is assumed that M_{MAX} is 1 and the reset operation is implemented only once.

After a failure is observed during the first set operation, when the reset operation and the further set operation are implemented, the number of failures is likely to be 0. After the reset operation and the further set operation are implemented, the variable resistance element 10 is read, the current is measured, and it is determined whether the measured current is greater than the reference current I_{RSET} (step S23). When the current flowing in the variable resistance element 10 is greater than the reference current I_{RSET} (YES in step S23), the set operation is completed.

Herein, assuming that the current flowing in the variable resistance element 10 is equal to or smaller than the reference current I_{RSET} (NO in step S23), the set operation count N is greater than the maximum number N_{MAX} (YES in step S24) and the reset operation count M is greater than a maximum number M_{MAX} (M_{MAX}=1) (YES in step S26). This situation is determined to be a setting failure.

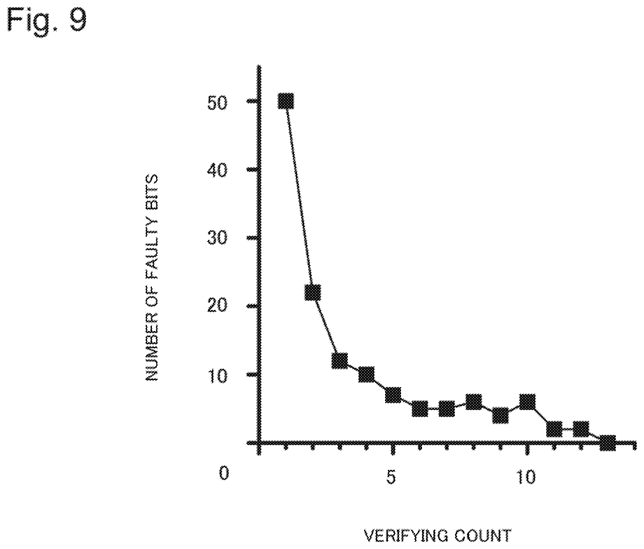

By the above operation, failures can be eliminated during the set operation that occur when the repetition count is equal to or more than 3,000. FIG. 9 illustrates how the number of faulty bits becomes 0 by the verifying during the set operation. The horizontal axis indicates a verify operation count, wherein a twelfth verify operation is relevant to the reset operation and the set operation, and the others are relevant to the set operation. The number of faulty bits becomes 0 by a thirteenth verify operation.

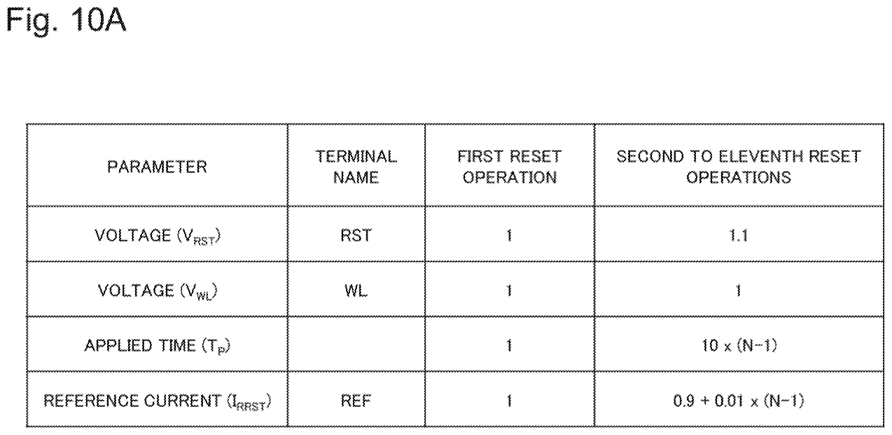

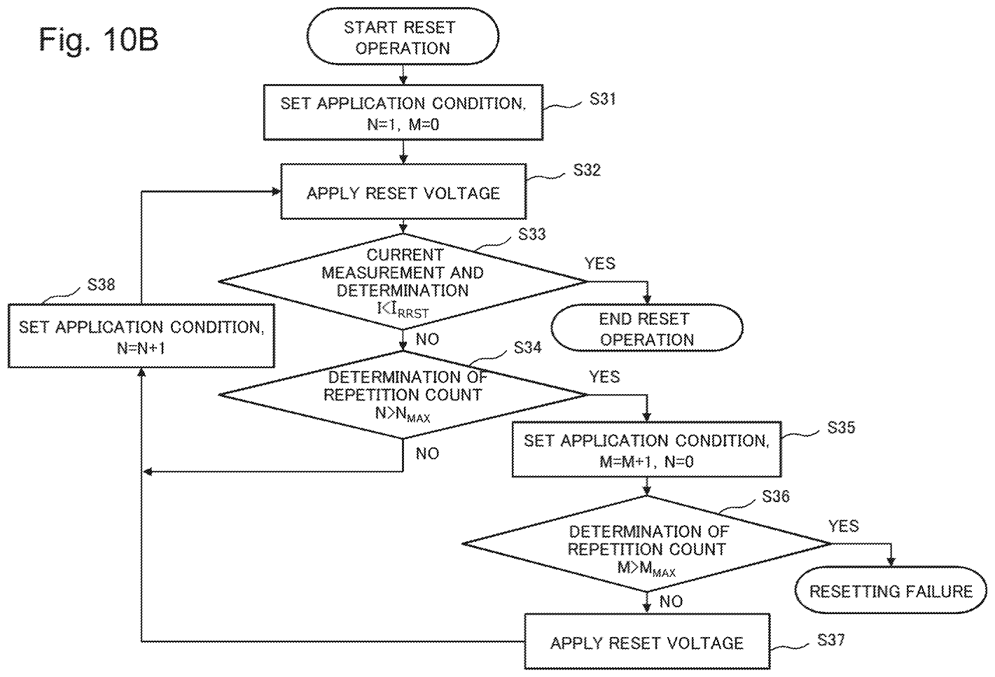

Next, the reset operation of each variable resistance element 10 will be described with reference to the flowchart in FIG. 10B. The reset operation is implemented in response to an address signal, relative to the variable resistance element 10 that is selected by the row decoder 51 and the column decoder 52. The application condition for applying voltage to each terminal is set, N=1 is set as the reset operation count, and M=0 is set as the set operation count (step S31). The voltage is applied to each terminal under the voltage application condition of a first reset operation (step S32). Next, the variable resistance element 10 is read, the current is measured, and it is determined whether the measured current is smaller than a reference current I_{RRST} (step S33). When the current flowing in the variable resistance element 10 is smaller than the reference current I_{RRST} (YES in step S33), the reset operation is completed. When the current flowing in the variable resistance element 10 is equal to or greater than the reference current I_{RRST} (NO in step S33), an application condition for applying voltage to each terminal is set in order to perform the reset operation twice (=N), N=N+1 is set (step S38), and the voltage is applied to each terminal (step S32). The application condition of a second reset operation that is a first verifying is as illustrated in the chart of FIG. 10A. Herein, voltage applied to an RST terminal is increased by 10%. Further, the applied time is increased by 10 times. Furthermore, in order to secure a margin during reading, the ON/OFF criterion is transitioned to the high resistance side.

When the reset operation count N is greater than the maximum number N_{MAX} (N_{MAX}=11), the set operation is performed by using the application condition of N=1 of FIG. 6B described according to the first example embodiment (step S37). Herein, N is set to 1, and the verifying of the reset operation is subsequently implemented after the set operation. It is assumed that M_{MAX} is set to 1, and the set operation is implemented only once.

After a failure is observed during the first reset operation, when the set operation and the further reset operation are implemented, the number of failures is likely to be 0. After the set operation and the further reset operation are implemented, the variable resistance element 10 is read, the current is measured, and it is determined that the measured current is smaller than the reference current I_{RRST} (step S33). When the current flowing in the reference change element 10 is smaller than the reference current I_{RRST} (YES in step S33), the reset operation is completed.

Herein, when it is assumed that the current flowing in the variable resistance element 10 is equal to or greater than the reference current I_{RRST} (NO in step S33), the reset operation count N is greater than the maximum number N_{MAX} (YES in step S34) and the reset operation count M is greater than the maximum number M_{MAX} (M_{MAX}=1) (YES in step S36). This situation is determined to be a resetting failure.

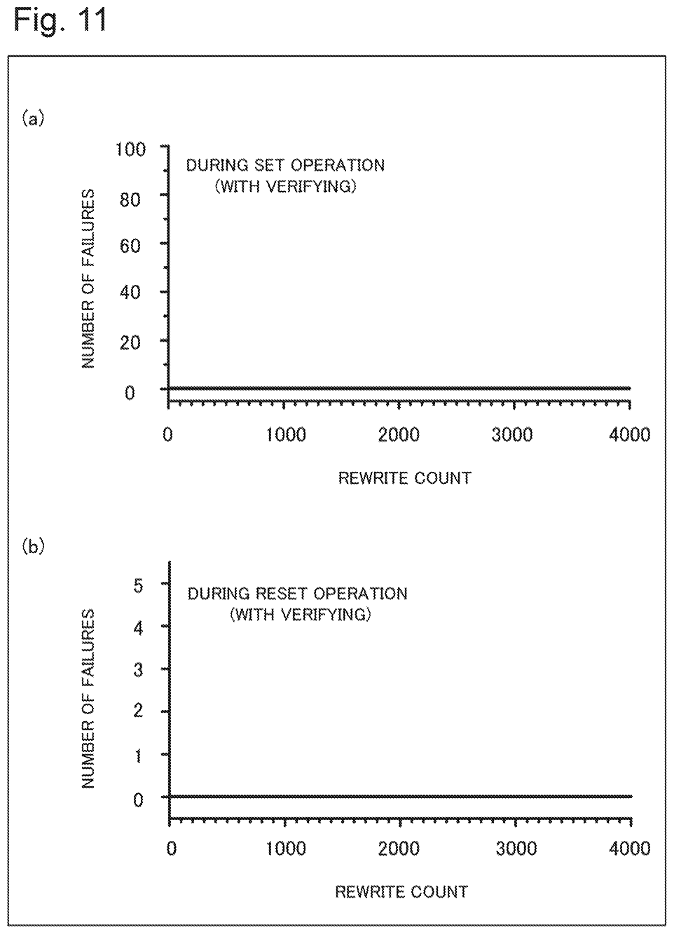

FIG. 11(a) and FIG. 11(b) illustrate the number of failures as a result of rewrite experiment of 128 Kbits up to 4,000 times according to the technique of the second example embodiment. During both the set operation of FIG. 11(a) and the reset operation of FIG. 11(b), failures can be eliminated.

The application conditions of FIGS. 8A and 8B and FIGS. 10A and 10B are results of optimization that is performed in such a way that the number of faulty bits becomes minimal, and it is possible to reduce the number of failures even when any of voltage adjustment, applied time adjustment, and reference current adjustment is performed. The range of adjustment may also be a value other than the values specifically illustrated in FIGS. 8A and 8B and FIGS. 10A and 10B. In addition, N_{MAX} and M_{MAX} are not limited to 11 and 1, respectively.

### Third Example Embodiment

Next, a rewrite method for a variable resistance element according to a third example embodiment will be described. The present example embodiment describes a method for optimizing application conditions required for a set operation and a reset operation. In order to avoid the cause of failures (S-iv) and (R-iii), it is desirable that the application conditions be not excessively great. In other words, it is desirable that a set voltage V_{SET}, a reset voltage V_{RST}, and a gate voltage V_{WL} be as small as possible, and it is desirable that applied time T_{P} be short. Further, the numbers of failures occurred during the set operation and the reset operation in a case where verifying is not implemented are desirable to be equal to each other.

In FIG. 4, the number of failures during the set operation is greater than the number of failures during the reset operation. It is clarified by experiment performed by the inventors, et al., that although the number of failures during the reset operation is increased by decreasing only the reset voltage V_{RST}, the number of failures during the set operation decreases. The number of failures during the reset operation and the number of failures during the set operation are made approximately equal to each other, and the maximum number of the rewrite count thereby increases.

When there is a large number of the setting failures and a small number of the resetting failures, the set voltage at a time when the count N=1 is increased or the reset voltage at a time when the count N=1 is decreased.

When there is a large number of the resetting failures and there is a small number of the setting failures, the reset voltage at the time when the count N=1 is increased or the reset voltage at the time when the count N=1 is decreased.

A variation on a wafer surface can also be restrained when one adjusts the application condition for each chip by a pre-shipment test. Rewriting of the order of 10 times is implemented on a typical chip without the verifying, and the application condition is adjusted.

While the invention has been particularly shown and described with reference to example embodiments thereof, the invention is not limited to these embodiments. The whole or part of the example embodiments disclosed above can be described as, but not limited to, the following supplementary notes.

### Supplementary Note 1

A rewrite method for a variable resistance element in which a variable resistance layer is disposed between a first electrode and a second electrode, and a resistance between the first electrode and the second electrode is reversibly changed when a write voltage between the first electrode and the second electrode is applied, the rewrite method for the variable resistance element including: after writing to the variable resistance element, reading the variable resistance element and measuring a read current; and comparing the measured read current with a reference current, changing a condition of the writing, based on the comparison result, and thereafter rewriting to the variable resistance element.

### Supplementary Note 2

The rewrite method for the variable resistance element according to supplementary note 1, wherein the condition of the writing includes voltage applied to the variable resistance element, current flowing in the variable resistance element, voltage applied time, and the reference current.

### Supplementary Note 3

The rewrite method for the variable resistance element according to supplementary note 1 or 2, wherein writing to the variable resistance element is a set operation of the variable resistance element, and the set operation is completed when the measured read current is greater than the reference current as a comparison result between the measured read current and the reference current.

### Supplementary Note 4

The rewrite method for the variable resistance element according to supplementary note 3, wherein, when the measured read current is smaller than the reference current as a comparison result between the measured read current and the reference current, the condition of the writing is changed, and thereafter the set operation of the variable resistance element is performed again.

### Supplementary Note 5

The rewrite method for the variable resistance element according to supplementary note 3, wherein, when the measured read current is smaller than the reference current as a comparison result between the measured read current and the reference current, a reset operation of the variable resistance element is performed, and thereafter the set operation of the variable resistance element is performed again.

### Supplementary Note 6

The rewrite method for the variable resistance element according to supplementary note 2, wherein writing to the variable resistance element is a reset operation of the variable resistance element, and the reset operation is completed when the measured read current is smaller than the reference current as a comparison result between the measured read current and the reference current.

### Supplementary Note 7

The rewrite method for the variable resistance element according to supplementary note 6, wherein, when the measured read current is greater than the reference current as a comparison result between the measured read current and the reference current, the condition of the writing is changed, and thereafter the reset operation of the variable resistance element is performed again.

### Supplementary Note 8

The rewrite method for the variable resistance element according to supplementary note 6, wherein, when the measured read current is greater than the reference current as a comparison result between the measured read current and the reference current, the set operation of the variable resistance element is performed, and thereafter the reset operation of the variable resistance element is performed again.

### Supplementary Note 9

The rewrite method for the variable resistance element according to any one of supplementary notes 1 to 8, wherein, in rewriting the variable resistance element, when there is a large number of setting failures of the variable resistance element and there is a small number of resetting failures of the variable resistance element or when there is a large number of resetting failures of the variable resistance element and there is a small number of setting failures of the variable resistance element, the condition of the writing is changed in such a way that the number of the setting failures of the variable resistance element and the number of the resetting failures of the variable resistance element are substantially equal to each other.

### Supplementary Note 10

A non-volatile storage device using a variable resistance element, comprising: the variable resistance element in which a variable resistance layer is disposed between a first electrode and a second electrode, and a resistance between the first electrode and the second electrode is reversibly changed when a write voltage between the first electrode and the second electrode is applied; and a control unit that is capable of applying voltage to the variable resistance element and is capable of comparing current flowing in the variable resistance element with a reference current, wherein the control unit performs: measurement processing of, after writing to the variable resistance element, reading the variable resistance element and measuring a read current; comparison processing of comparing the measured read current with the reference current; and changing a condition of the writing, based on the comparison result of the comparison processing, and thereafter rewriting to the variable resistance element.

### Supplementary Note 11

The non-volatile storage device using the variable resistance element according to supplementary note 10, wherein the condition of the writing includes voltage applied to the variable resistance element, current flowing in the variable resistance element, voltage applied time, and the reference current.

### Supplementary Note 12

The non-volatile storage device using the variable resistance element according to supplementary note 10 or 11, wherein, when writing to the variable resistance element is a set operation of the variable resistance element, the control unit completes the set operation when the measured read current is greater than the reference current as a comparison result between the measured read current and the reference current.

### Supplementary Note 13

The non-volatile storage device using the variable resistance element according to supplementary note 12, wherein, when the measured read current is smaller than the reference current as a comparison result between the measured read current and the reference current, the control unit changes the condition of the writing, and thereafter performs the set operation of the variable resistance element again.

### Supplementary Note 14

The non-volatile storage device using the variable resistance element according to supplementary note 12, wherein, when the measured read current is smaller than the reference current as a comparison result between the measured read current and the reference current, the control unit performs a reset operation of the variable resistance element, and thereafter performs the set operation of the variable resistance element again.

### Supplementary Note 15

The non-volatile storage device using the variable resistance element according to supplementary note 10 or 11, wherein, when writing to the variable resistance element is a reset operation of the variable resistance element, the control unit completes the reset operation when the measured read current is smaller than the reference current as a comparison result between the measured read current and the reference current.

### Supplementary Note 16

The non-volatile storage device using the variable resistance element according to supplementary note 15, wherein, when the measured read current is greater than the reference current as a comparison result between the measured read current and the reference current, the control unit changes the condition of the writing, and thereafter performs the reset operation of the variable resistance element again.

### Supplementary Note 17

The non-volatile storage device using the variable resistance element according to supplementary note 15, wherein, when the measured read current is greater than the reference current as a comparison result between the measured read current and the reference current, the control unit performs a set operation of the variable resistance element, and thereafter performs the reset operation of the variable resistance element again.

### Supplementary Note 18

The non-volatile storage device using the variable resistance element according to any one of supplementary notes 10 to 17, wherein, in rewriting the variable resistance element, when there is a large number of setting failures of the variable resistance element and there is a small number of resetting failures of the variable resistance element or when there is a large number of resetting failures of the variable resistance element and there is a small number of setting failures of the variable resistance element, the control unit changes the condition of the writing in such a way that the number of the setting failures of the variable resistance element and the number of the resetting failures of the variable resistance element are substantially equal to each other.

### Supplementary Note 19

The non-volatile storage device using the variable resistance element according to supplementary note 18, wherein, in rewriting the variable resistance element, when there is a large number of setting failures of the variable resistance element and there is a small number of resetting failures of the variable resistance element, the control unit changes the condition of the writing by increasing a set voltage for rewriting the variable resistance element or decreasing a reset voltage for rewriting the variable resistance element, and.

### Supplementary Note 20

The non-volatile storage device using the variable resistance element according to supplementary note 18, wherein, in rewriting the variable resistance element, when there is a large number of resetting failures of the variable resistance element and there is a small number of setting failures of the variable resistance element, the control unit changes the condition of the writing by increasing a reset voltage for rewriting the variable resistance element or decreasing a set voltage for rewriting the variable resistance element.

While the invention has been particularly shown and described with reference to example embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent application No. 2017-206267 filed on Oct. 25, 2017, the disclosure of which is incorporated herein in its entirety by reference.

### REFERENCE SIGNS LIST

1 Variable resistance element cell
2 Variable resistance element cell array
10 Variable resistance element
11 First electrode
12 Variable resistance layer
13 Second electrode
14 Gate electrode
15 Upper terminal
16 Lower terminal
20 n-type MOSFET
51 Row decoder
52 Column decoder
53 Column switch
60 Read circuit
70 Control circuit

What is claimed is:

1. A rewrite method for a variable resistance element in which a variable resistance layer is disposed between a first electrode and a second electrode, and a resistance between the first electrode and the second electrode is reversibly changed when a write voltage between the first electrode and the second electrode is applied, the rewrite method for the variable resistance element, comprising:
after writing to the variable resistance element, reading the variable resistance element and measuring a read current; and
comparing the measured read current with a reference current, changing a condition of the writing, based on the comparison result, and thereafter rewriting to the variable resistance element.

2. The rewrite method for the variable resistance element according to claim 1, wherein
the condition of the writing includes voltage applied to the variable resistance element, current flowing in the variable resistance element, voltage applied time, and the reference current.

3. The rewrite method for the variable resistance element according to claim 1, wherein
writing to the variable resistance element is a set operation of the variable resistance element, and the set operation is completed when the measured read current is greater than the reference current as a comparison result between the measured read current and the reference current.

4. The rewrite method for the variable resistance element according to claim 3, wherein,
when the measured read current is smaller than the reference current as a comparison result between the measured read current and the reference current, the condition of the writing is changed, and thereafter the set operation of the variable resistance element is performed again.

5. The rewrite method for the variable resistance element according to claim 3, wherein,
when the measured read current is smaller than the reference current as a comparison result between the measured read current and the reference current, a reset operation of the variable resistance element is performed, and thereafter the set operation of the variable resistance element is performed again.

6. The rewrite method for the variable resistance element according to claim 2, wherein
writing to the variable resistance element is a reset operation of the variable resistance element, and the reset operation is completed when the measured read current is smaller than the reference current as a comparison result between the measured read current and the reference current.

7. The rewrite method for the variable resistance element according to claim 6, wherein,
when the measured read current is greater than the reference current as a comparison result between the measured read current and the reference current, the condition of the writing is changed, and thereafter the reset operation of the variable resistance element is performed again.

8. The rewrite method for the variable resistance element according to claim 6, wherein,
when the measured read current is greater than the reference current as a comparison result between the measured read current and the reference current, the set operation of the variable resistance element is performed, and thereafter the reset operation of the variable resistance element is performed again.

9. The rewrite method for the variable resistance element according to claim 1, wherein,
in rewriting the variable resistance element, when there is a large number of setting failures of the variable resistance element and there is a small number of resetting failures of the variable resistance element, or when there is a large number of resetting failures of the variable resistance element and there is a small number of setting failures of the variable resistance element, the condition of the writing is changed in such a way that the number of the setting failures of the variable resistance element and the number of the resetting failures of the variable resistance element are substantially equal to each other.

10. A non-volatile storage device using a variable resistance element, comprising:
the variable resistance element in which a variable resistance layer is disposed between a first electrode and a second electrode, and a resistance between the first electrode and the second electrode is reversibly changed when a write voltage between the first electrode and the second electrode is applied; and
a control unit that is capable of applying voltage to the variable resistance element and is capable of comparing current flowing in the variable resistance element with a reference current, wherein
the control unit performs:
measurement processing of, after writing to the variable resistance element, reading the variable resistance element and measuring a read current;
comparison processing of comparing the measured read current with the reference current; and
changing a condition of the writing, based on the comparison result of the comparison processing, and thereafter rewriting to the variable resistance element.

11. The non-volatile storage device using the variable resistance element according to claim 10, wherein
the condition of the writing includes voltage applied to the variable resistance element, current flowing in the variable resistance element, voltage applied time, and the reference current.

12. The non-volatile storage device using the variable resistance element according to claim 10, wherein,
when writing to the variable resistance element is a set operation of the variable resistance element, the control unit completes the set operation when the measured read current is greater than the reference current as a comparison result between the measured read current and the reference current.

13. The non-volatile storage device using the variable resistance element according to claim 12, wherein,
when the measured read current is smaller than the reference current as a comparison result between the measured read current and the reference current, the control unit changes the condition of the writing, and thereafter performs the set operation of the variable resistance element again.

14. The non-volatile storage device using the variable resistance element according to claim 12, wherein,
when the measured read current is smaller than the reference current as a comparison result between the measured read current and the reference current, the control unit performs a reset operation of the variable resistance element, and thereafter performs the set operation of the variable resistance element again.

15. The non-volatile storage device using the variable resistance element according to claim 10, wherein,
when writing to the variable resistance element is a reset operation of the variable resistance element, the control unit completes the reset operation when the measured read current is smaller than the reference current as a comparison result between the measured read current and the reference current.

16. The non-volatile storage device using the variable resistance element according to claim 15, wherein,
when the measured read current is greater than the reference current as a comparison result between the measured read current and the reference current, the control unit changes the condition of the writing, and thereafter performs the reset operation of the variable resistance element again.

17. The non-volatile storage device using the variable resistance element according to claim 15, wherein,
when the measured read current is greater than the reference current as a comparison result between the measured read current and the reference current, the control unit performs a set operation of the variable resistance element, and thereafter performs the reset operation of the variable resistance element again.

18. The non-volatile storage device using the variable resistance element according to claim 10, wherein,
in rewriting the variable resistance element, when there is a large number of setting failures of the variable resistance element and there is a small number of resetting failures of the variable resistance element, or when there is a large number of resetting failures of the variable resistance element and there is a small number of setting failures of the variable resistance element, the control unit changes the condition of the writing in such a way that the number of the setting failures of the variable resistance element and the number of the resetting failures of the variable resistance element are substantially equal to each other.

19. The non-volatile storage device using the variable resistance element according to claim 18, wherein,
in rewriting the variable resistance element, when there is a large number of setting failures of the variable resistance element and there is a small number of resetting failures of the variable resistance element, the control unit changes the condition of the writing by increasing a set voltage for rewriting the variable resistance element or decreasing a reset voltage for rewriting the variable resistance element.

20. The non-volatile storage device using the variable resistance element according to claim 18, wherein,
in rewriting the variable resistance element, when there is a large number of resetting failures of the variable resistance element and there is a small number of setting failures of the variable resistance element, the control unit changes the condition of the writing by increasing a reset voltage for rewriting the variable resistance element or decreasing a set voltage for rewriting the variable resistance element.
